(19) United States
(12) Patent Application Publication
(10) Pub. No.: US 2024/0181539 A1
(43) Pub. Date: Jun. 6, 2024

(54) COATED TOOL AND CUTTING TOOL

(71) Applicant: KYOCERA CORPORATION, Kyoto (JP)

(72) Inventor: Kei YOSHIMI, Satsumasendai-shi, Kagoshima (JP)

(21) Appl. No.: 18/574,306

(22) PCT Filed: Jul. 7, 2022
(86) PCT No.: PCT/JP2022/027012

§ 371 Date: Dec. 27, 2023

(30) Foreign Application Priority Data
Jul. 30, 2021 (JP) 2021-125930

(51) Int. Cl. B23B 27/14

(52) U.S. Cl. CPC B23B 27/14

(57) ABSTRACT

A coated tool according to an aspect of the present disclosure includes a base body, and a coating layer of at least one layer located on the base body. The coating layer contains a cubic crystal composed of at least one element selected from Groups 4a, 5a and 6a elements in the periodic table, Al and Si, and at least one element selected from C and N. The coating layer has a maximum value (I₁ₘₐₓ) of an X-ray intensity in a measurement range of 0° or greater and 90° or less on an X-ray intensity distribution of an α-axis of a positive pole figure related to a (111) plane of the cubic crystal, and an angle region (θ_{1F}) having an X-ray intensity of 85% or more of I₁ₘₐₓ occupies 90% or more in a region of 30° or greater and 90° or less.

### CROSS-REFERENCE TO RELATED APPLICATIONS

This application is national stage application of International Application No. PCT/JP2022/027012, filed on Jul. 7, 2022, which claims the benefit of priority from Japanese Patent Application No. 2021-125930, filed on Jul. 30, 2021.

### TECHNICAL FIELD

The present disclosure relates to a coated tool and a cutting tool.

### BACKGROUND OF INVENTION

As a tool used for cutting processing such as turning processing or milling processing, a coated tool is known in which a surface of a base body made of cemented carbide, cermet, ceramic, or the like is coated with a coating layer to improve wear resistance, and the like.

### CITATION LIST

### Patent Literature

Patent Document 1: WO2019/146710
Patent Document 2: WO2011/016488
Patent Document 3: WO2010/007958

### SUMMARY

A coated tool according to an aspect of the present disclosure includes a base body, and a coating layer of at least one layer located on the base body. The coating layer contains a cubic crystal composed of at least one element selected from Groups 4a, 5a and 6a elements in the periodic table, Al and Si, and at least one element selected from C and N. The coating layer has a maximum value of X-ray intensity (I₁ₘₐₓ) in a measurement range of an α-axis angle of 0° or greater and 90° or less on an X-ray intensity distribution of an α-axis of a positive pole figure related to a (111) plane of the cubic crystal, and an angle region (θ_{1F}) having an X-ray intensity of 85% or more of I₁ₘₐₓ occupies 90% or more in a region of 30° or greater and 90° or less.

### BRIEF DESCRIPTION OF THE DRAWINGS

FIG. 1 is a perspective view illustrating an example of a coated tool according to an embodiment.

FIG. 2 is a side sectional view illustrating the example of the coated tool according to the embodiment.

FIG. 3 is a sectional view illustrating an example of a coating layer according to the embodiment.

FIG. 4 is a schematic enlarged view of a portion H illustrated in FIG. 3.

FIG. 5 is a graph showing an X-ray intensity distribution of a positive pole figure related to a (111) plane of a cubic crystal included in the coating layer according to the embodiment.

FIG. 6 is a graph showing an X-ray intensity distribution of a positive pole figure related to a (200) plane of the cubic crystal included in the coating layer according to the embodiment.

FIG. 7 is a front view illustrating an example of a cutting tool according to the embodiment.

FIG. 8 is a table summarizing various numerical values on the X-ray intensity distribution of the positive pole figure related to the (111) plane of the cubic crystal contained in the coating layer for Samples No. 1 to No. 8.

FIG. 9 is a table summarizing various numerical values on the X-ray intensity distribution of the positive pole figure related to the (200) plane of the cubic crystal contained in the coating layer for Samples No. 1 to No. 6.

FIG. 10 is a table summarizing results of cutting tests performed on Samples No. 1 to No. 8.

### DESCRIPTION OF EMBODIMENTS

The following is a detailed description of a coated tool and a cutting tool according to the present disclosure (hereinafter referred to as “embodiments”) with reference to the drawings. It should be noted that the coated tool and the cutting tool according to the present disclosure are not limited by the embodiments. Embodiments can be appropriately combined so as not to contradict each other in terms of processing content. In the following embodiments, the same portions are denoted by the same reference signs, and overlapping explanations are omitted.

In the embodiments described below, expressions such as “constant”, “orthogonal”, “perpendicular”, and “parallel” may be used, but these expressions do not need to be exactly “constant”, “orthogonal”, “perpendicular”, and “parallel”. In other words, each of the above-described expressions allows for deviations in, for example, manufacturing accuracy, positioning accuracy, and the like.

In the related art described above, there is room for further improvement in terms of enhancing impact resistance.

### Coated Tool

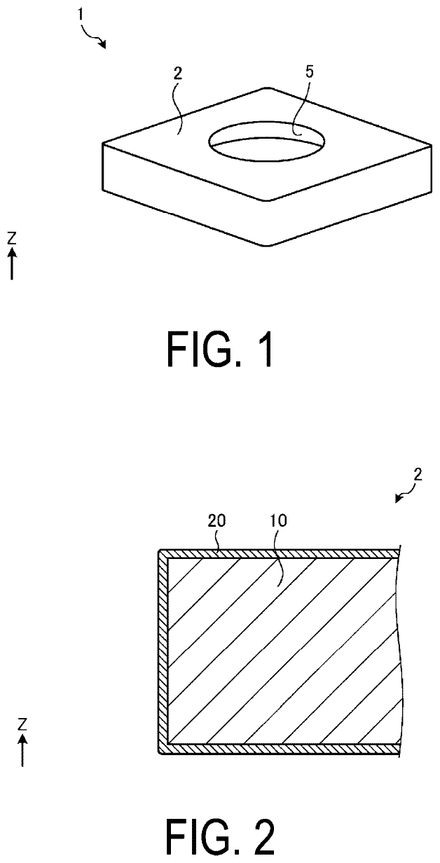

FIG. 1 is a perspective view illustrating an example of a coated tool according to an embodiment. FIG. 2 is a side sectional view illustrating an example of the coated tool 1 according to the embodiment. As illustrated in FIG. 1, a coated tool 1 according to the embodiment includes a tip body 2.

### Tip Body 2

The tip body 2 has a hexagonal shape in which a shape of an upper surface and a lower surface (a surface intersecting the Z-axis illustrated in FIG. 1) is a parallelogram.

One corner portion of the tip body 2 functions as a cutting edge portion. The cutting edge portion has a first surface (for example, an upper surface) and a second surface (for example, a side surface) connected to the first surface. In the embodiment, the first surface functions as a “rake face” for scooping chips generated by cutting, and the second surface functions as a “flank face”. A cutting edge is located on at least a part of a ridge line where the first surface and the second surface intersect with each other, and the coated tool 1 cuts a work material through application of the cutting edge to the work material.

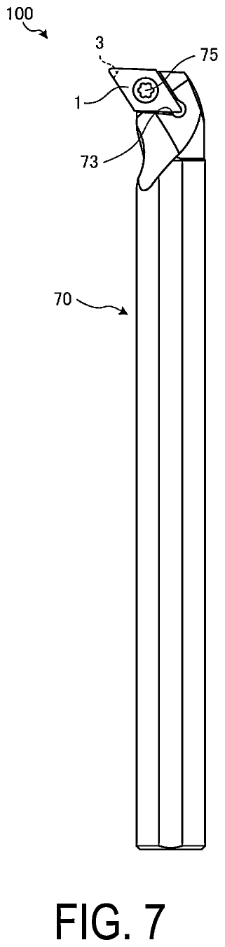

A through hole 5 that vertically penetrates the tip body 2 is located in the center portion of the tip body 2. A screw 75 for attaching the coated tool 1 to a holder 70 described below is inserted into the through hole 5 (see FIG. 7).

As illustrated in FIG. 2, the tip body 2 has a base body 10, and a coating layer 20.

### Base Body 10

The base body 10 is formed of, for example, cemented carbide. The cemented carbide contains tungsten (W), specifically, tungsten carbide (WC). Further, the cemented carbide may contain nickel (Ni) or cobalt (Co). For example, the base body 10 is made of WC-based cemented carbide containing hard particles made of WC as a hard phase component and Co as a main component of a binder phase.

Alternatively, the base body 10 may be formed of a cermet. The cermet contains, for example, titanium (Ti), specifically, titanium carbide (TiC) or titanium nitride (TiN). Furthermore, the cermet may contain Ni or Co.

The base body 10 may be formed of a cubic boron nitride sintered body containing cubic boron nitride (cBN) particles. The base body 10 is not limited to the cubic boron nitride (cBN) particles, and may contain particles such as hexagonal boron nitride (hBN), rhombohedral boron nitride (rBN) and wurtzite boron nitride (wBN).

### Coating Layer 20

The coating layer 20 is coated on the base body 10 for the purpose of, for example, improving wear resistance, heat resistance, and the like of the base body 10. In the example in FIG. 2, the coating layer 20 entirely coats the base body 10. The coating layer 20 may be located at least on the base body 10. When the coating layer 20 is located on a first surface (here, an upper surface) of the base body 10, the first surface has high wear resistance and heat resistance. When the coating layer 20 is located on a second surface (here, a side surface) of the base body 10, the second surface has high wear resistance and heat resistance.

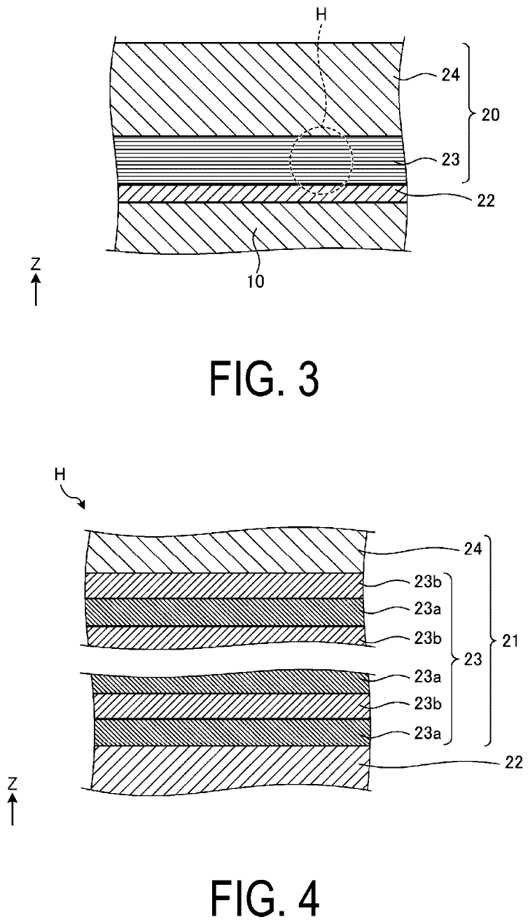

Here, a specific configuration of the coating layer 20 will be described with reference to FIG. 3. FIG. 3 is a sectional view illustrating an example of the coating layer 20 according to the embodiment.

As illustrated in FIG. 3, the coating layer 20 is a layer having excellent wear resistance, as compared with an intermediate layer 22 described below. The coating layer 20 has one or more metal nitride layers. The coating layer 20 may include a first coating layer 23 in which a plurality of metal nitride layers are layered, and a second coating layer 24 located on the first coating layer 23.

The coating layer 20 contains a cubic crystal composed of at least one element selected from Group 4a, 5a and 6a elements in the periodic table, Al and Si, and at least one element selected from C and N. Note that Group 4a elements are Ti, Zr, Hf and Rf, Group 5a elements are V, Nb, Ta and db, and Group 6a elements are Cr, Mo, W and Sg. The configuration of the coating layer 20 will be described below.

### Intermediate Layer 22

An intermediate layer 22 may be located between the base body 10 and the coating layer 20. Specifically, the intermediate layer 22 has one surface (here, a lower surface) in contact with the upper surface of the base body 10 and another surface (here, an upper surface) in contact with the lower surface of the coating layer 20 (first coating layer 23).

The intermediate layer 22 has higher adhesion to the base body 10 than to the coating layer 20. Examples of a metal element having such characteristics include Zr, Hf, V, Nb, Ta, Cr, Mo, W, Al, Si, Y, and Ti. The intermediate layer 22 contains at least one metal element among the above-described metal elements. For example, the intermediate layer 22 may contain Ti. Note that Si is a metalloid element, but in the present specification, it is assumed that a metalloid element is also included in the metal element.

When the intermediate layer 22 contains Ti, the content of Ti in the intermediate layer 22 may be 1.5 atomic % or more. For example, the content of Ti in the intermediate layer 22 may be 2.0 atomic % or more.

The intermediate layer 22 may contain components other than the above-described metal elements (Zr, Hf, V, Nb, Ta, Cr, Mo, W, Al, Si, Y, and Ti). However, from the standpoint of adhesion to the base body 10, the intermediate layer 22 may contain at least 95 atomic % or more of the metal elements in a combined amount. More preferably, the intermediate layer 22 may contain 98 atomic % or more of the metal elements in a combined amount. Note that the ratio of the metal components in the intermediate layer 22 can be identified by, for example, analysis using an energy dispersive X-ray spectrometer (EDS) attached to a scanning transmission electron microscope (STEM).

As described above, in the coated tool 1 according to the embodiment, by providing the intermediate layer 22 having higher wettability with the base body 10 than the coating layer 20 between the base body 10 and the coating layer 20, the adhesion between the base body 10 and the coating layer 20 can be improved. Note that since the intermediate layer 22 also has high adhesion to the coating layer 20, the coating layer 20 is less likely to peel off from the intermediate layer 22.

The intermediate layer 22 may be formed using an arc ion plating method (AIP method). The AIP method is a method in which target metals are evaporated using an arc discharge in a vacuum atmosphere, and are combined with N2 gas to form metal nitrides. At this time, the bias voltage applied to the base body 10, which is a coated object, may be 400 V or more. Note that the coating layer 20 may also be formed by the AIP method.

Note that a thickness of the intermediate layer 22 may be, for example, 0.1 nm or greater and less than 20.0 nm.

### First Coating Layer 23 and Second Coating Layer 24

The configuration of the first coating layer 23 and the second coating layer 24 will be described with reference to FIG. 4. FIG. 4 is a schematic enlarged view of a portion H illustrated in FIG. 3.

As illustrated in FIG. 4, the coating layer 20 includes a first coating layer 23 located on the intermediate layer 22, and a second coating layer 24 located on the first coating layer 23.

The first coating layer 23 includes a plurality of first layers 23a and a plurality of second layers 23b. The first coating layer 23 has a striped configuration in which the first layer 23a and the second layer 23b are alternately stacked in a thickness direction.

The thickness of each of the first layer 23a and the second layer 23b may be 50 nm or less. Since the first layer 23a and the second layer 23b formed to be thin have small residual stresses and are less likely to cause peeling, cracking, or the like, the durability of the coating layer 20 is enhanced.

The first layer 23a is a layer in contact with the intermediate layer 22, and the second layer 23b is formed on the first layer 23a.

The first coating layer 23, specifically, the first layer 23a and the second layer 23b may be made of at least one element selected from the group consisting of Al, Cr, Si, Group 5 elements, Group 6 elements, and Group 4 elements except for Ti, and at least one element selected from the group consisting of C and N. Specifically, the first layer 23a and the second layer 23b may include at least one element selected from the group consisting of Al, Group 5 elements, Group 6 elements, and Group 4 elements except for Ti, at least one element selected from the group consisting of C and N, Si, and Cr.

More specifically, the first layer 23a and the second layer 23b may include Al, Cr, Si, and N. That is, the first layer 23a and the second layer 23b may be an AlCrSiN layer containing AlCrSiN, which is a nitride of Al, Cr and Si. Note that the expression “AlCrSiN” means that Al, Cr, Si, and N are present at an arbitrary ratio, and does not necessarily mean that Al, Cr, Si, and N are present at a ratio of 1:1:1:1.

In this way, the first layer 23a containing the metal (for example, Si) included in the intermediate layer 22 is located on the intermediate layer 22, and thus the adhesion between the intermediate layer 22 and the coating layer 20 is high. This makes it difficult for the coating layer 20 to peel off from the intermediate layer 22, so the durability of the coating layer 20 is high.

The first layer 23a and the second layer 23b may each contain Al, Cr, Si, and N. Here, the content of Al in the first layer 23a is referred to as the first Al content, the content of Cr in the first layer 23a is referred to as the first Cr content, and the content of Si in the first layer 23a is referred to as the first Si content. The content of Al in the second layer 23b is referred to as the second Al content, the content of Cr in the second layer 23b is referred to as the second Cr content, and the content of Si in the second layer 23b is referred to as the second Si content.

In this case, the first Al content may be greater than the second Al content, the first Cr content may be less than the second Cr content, and the first Si content may be greater than the second Si content. A sum of Al, Cr, and Si of the metal elements contained in the first coating layer 23 may be 98 atomic % or more.

The second coating layer 24 may include Ti, Si, and N. That is, the second coating layer 24 may be a nitride layer (TiSiN layer) containing Ti and Si. Note that the expression “TiSiN layer” means that Ti, Si, and N are present at an arbitrary ratio, and does not necessarily mean that Ti, Si, and N are present at a ratio of 1:1:1.

As a result, for example, when a coefficient of friction of the second coating layer 24 is low, the welding resistance of the coated tool 1 can be improved. For example, when the hardness of the second coating layer 24 is high, the wear resistance of the coated tool 1 can be improved. For example, when an oxidation start temperature of the second coating layer 24 is high, the oxidation resistance of the coated tool 1 can be improved.

The second coating layer 24 may have a striped structure in which at least two layers are located in the thickness direction. Each layer included in the striped structure of the second coating layer 24 may contain, for example, Ti, Si, and N. In this case, in the second coating layer 24, the content of Ti (hereinafter referred to as “Ti content”), the content of Si (hereinafter referred to as “Si content”), and the content of N (hereinafter referred to as “N content”) may each repeatedly increase and decrease along the thickness direction of the second coating layer 24. A sum of Ti and Si of the metal elements contained in the second coating layer 24 may be 98 atomic % or more. The second coating layer 24 may include a third layer and a fourth layer alternately located in the thickness direction.

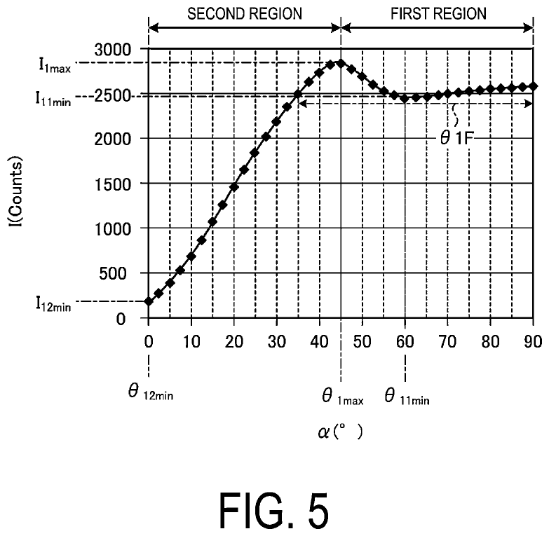

X-Ray Intensity Distribution of Positive Pole Figure Related to (111) Plane FIG. 5 is a graph showing an X-ray intensity distribution of a positive pole figure related to a (111) plane of a cubic crystal included in the coating layer 20 according to the embodiment. A horizontal axis of the positive pole figure shown in FIG. 5 represents an angle of an α-axis (tilt axis), and a vertical axis represents an X-ray intensity in a tilt direction.

The orientability of the (111) plane in a cubic crystal can be evaluated by an X-ray intensity distribution of a positive pole figure related to the (111) plane. For example, when there is a peak at a position of 45° on the X-ray intensity distribution of the positive pole figure related to the (111) plane, the number of cubic crystals in which the (111) plane is inclined by 45° with respect to the surface of the base body 10 is large.

As shown in FIG. 5, the coating layer 20 according to the embodiment has a maximum value I₁ₘₐₓ of the X-ray intensity in a measurement range of the α-axis angle of 0° or greater and 90° or less on the X-ray intensity distribution of the α-axis of the positive pole figure related to the (111) plane of the cubic crystal.

Here, an angle region of the α-axis in which the intensity is 85% or more of I₁ₘₐₓ is denoted as θ_{1F}. In the coating layer 20 according to the embodiment, θ_{1F} may be 90% or more in a region where the angle of the α-axis is 30° or greater and 90° or less. According to such a configuration, since the crystal orientations are aligned to some extent, sudden defects are reduced. Therefore, the coated tool 1 having the coating layer 20 of such a configuration has high impact resistance.

In the positive pole figure related to the (111) plane shown in FIG. 5, an angle region on a higher angle side than the angle θ₁ₘₐₓ of the α-axis indicating I₁ₘₐₓ is referred to as a first region, and an angle region on a lower angle side than θ₁ₘₐₓ is referred to as a second region. The minimum value of the X-ray intensity in the first region is denoted as I₁₁ₘᵢₙ, and the minimum value of the X-ray intensity in the second region is denoted as I₁₂ₘᵢₙ.

In this case, in the coating layer 20, a difference between I₁ₘₐₓ and I₁₁ₘᵢₙ (I₁ₘₐₓ−I₁₁ₘᵢₙ) may be smaller than a difference between I₁ₘₐₓ and I₁₂ₘᵢₙ (I₁ₘₐₓ−I₁₂ₘᵢₙ), and I₁₁ₘᵢₙ may be 85% or more of I₁ₘₐₓ.

When the orientability of the coating layer 20 is configured as described above, a region having high crystal orientability is present in the coating layer 20. Consequently, the coated tool 1 having the coating layer 20 can withstand impacts from various directions. Therefore, the coated tool 1 according to the embodiment has high impact resistance.

In the positive pole figure related to the (111) plane shown in FIG. 5, in the coating layer 20, I₁₂ₘᵢₙ may be 5% or greater and 20% or less of I₁ₘₐₓ.

When the orientability of the coating layer 20 is configured as described above, the orientation in a direction in which the impact on the coating layer 20 is weak can be reduced. Thereby, many orientations can be aligned in a direction in which the impact is strong. Therefore, the coated tool 1 having the coating layer 20 has high impact resistance.

In the positive pole figure related to the (111) plane shown in FIG. 5, the coating layer 20 may have θ₁ₘₐₓ of 35° or greater and 55° or less.

When θ₁ₘₐₓ is within this range, the coating layer 20 is resistant to impacts from both horizontal and vertical directions. Therefore, the coated tool 1 having the coating layer 20 has high impact resistance.

In the positive pole figure related to the (111) plane shown in FIG. 5, the coating layer 20 may have at least one inflection point in the first region.

When the orientability of the coating layer 20 is configured as described above, a region where the orientability is high can be increased. Therefore, the coated tool 1 having the coating layer 20 has high impact resistance.

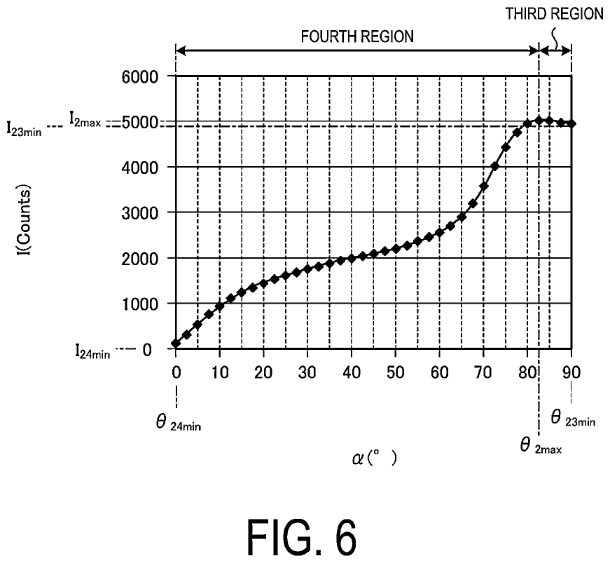

X-Ray Intensity Distribution of Positive Pole Figure Related to (200) Plane FIG. 6 is a graph showing an X-ray intensity distribution of a positive pole figure related to a (200) plane of a cubic crystal included in the coating layer 20 according to the embodiment. A horizontal axis of the positive pole figure shown in FIG. 6 represents an angle of an α-axis (tilt axis), and a vertical axis represents an X-ray intensity in a tilt direction.

As shown in FIG. 6, the coating layer 20 according to the embodiment has a maximum value I₂ₘₐₓ of the X-ray intensity in a measurement range of the α-axis angle of 0° or greater and 90° or less on the X-ray intensity distribution of the α-axis of the positive pole figure related to the (200) plane of the cubic crystal. Here, an angle of the α-axis indicating I₂ₘₐₓ is referred to as θ₂ₘₐₓ, an angle region on a higher angle side than θ₂ₘₐₓ is referred to as a third region, and an angle region on a lower angle side than θ₂ₘₐₓ is referred to as a fourth region. A minimum value of the X-ray intensity in the third region is denoted as I₂₃ₘᵢₙ, and a minimum value of the X-ray intensity in the fourth region is denoted as I₂₄ₘᵢₙ.

In the positive pole figure related to the (200) plane shown in FIG. 6, in the coating layer 20, a difference (I₂ₘₐₓ−I₂₃ₘᵢₙ) between I₂ₘₐₓ and I₂₃ₘᵢₙ may be smaller than a difference (I₂ₘₐₓ−I₂₄ₘᵢₙ) between I₂ₘₐₓ and I₂₄ₘᵢₙ, and I₂₃ₘᵢₙ may be 95% or more of I₂ₘₐₓ.

When the coating layer 20 has such a configuration, the coating layer 20 includes a region having a strength close to I₂ₘₐₓ, and can suppress chipping and damage caused by impacts from various directions. Therefore, the coated tool 1 having the coating layer 20 has high impact resistance.

In the positive pole figure related to the (200) plane shown in FIG. 6, in the coating layer 20, I₂₄ₘᵢₙ may be 2% or greater and 35% or less of I₂ₘₐₓ.

When the orientability of the coating layer 20 is configured as described above, the orientation in a direction in which the impact on the coating layer 20 is weak can be reduced. Thereby, many orientations can be aligned in a direction in which the impact is strong. Therefore, the coated tool 1 having the coating layer 20 has high impact resistance.

In the positive pole figure related to the (200) plane shown in FIG. 6, the coating layer 20 according to the embodiment may have θ₂ₘₐₓ of 70° or greater and 85° or less.

When θ₂ₘₐₓ is within this range, the coating layer 20 is resistant to impacts from both horizontal and vertical directions. Therefore, the coated tool 1 having the coating layer 20 has high impact resistance.

The coating layer 20 can be located on the base body 10 by using, for example, a physical vapor deposition (PVD) method. For example, in a case where the coating layer 20 is formed by using the above-described vapor deposition method while the base body 10 is held on an inner peripheral surface of the through hole 5, the coating layer 20 can be positioned to entirely cover a surface of the base body 10 except for the inner peripheral surface of the through hole 5.

### Cutting Tool

A configuration of a cutting tool including the coated tool 1 described above will be described with reference to FIG. 7. FIG. 7 is a front view illustrating an example of a cutting tool according to the embodiment.

As illustrated in FIG. 7, a cutting tool 100 according to the embodiment includes the coated tool 1 and a holder 70 for fixing the coated tool 1.

The holder 70 is a rod-like member extending from a first end (upper end in FIG. 7) toward a second end (lower end in FIG. 7). The holder 70 is made of, for example, steel or cast iron. In particular, it is preferable to use steel having high toughness among these members.

The holder 70 has a pocket 73 at an end portion on the first end side. The pocket 73 is a portion in which the coated tool 1 is mounted, and has a seating surface intersecting with the rotation direction of the work material and a binding side surface inclined with respect to the seating surface. A screw hole into which a screw 75 described later is screwed is provided on the seating surface.

The coated tool 1 is located in the pocket 73 of the holder 70, and is mounted on the holder 70 by the screw 75. That is, the screw 75 is inserted into the through hole 5 of the coated tool 1, and the tip end of the screw 75 is inserted into the screw hole formed in the seating surface of the pocket 73, and the screw portions are screwed together. Thus, the coated tool 1 is mounted on the holder 70 such that the cutting edge portion protrudes outward from the holder 70.

In the embodiment, a cutting tool used for so-called turning processing is exemplified. Examples of the turning processing include boring, external turning, and groove-forming. Note that, a cutting tool is not limited to those used in the turning processing. For example, the coated tool 1 may be used as a cutting tool used for milling processing. Examples of the cutting tool used for milling processing may include milling cutters such as a plain milling cutter, a face milling cutter, a side milling cutter, and a groove milling cutter, and end mills such as a single-blade end mill, a multi-blade end mill, a taper-blade end mill, and a ball end mill.

### Manufacturing Method

An example of a manufacturing method of the coated tool 1 according to the embodiment will be described. Note that the manufacturing method of the coated tool according to the embodiment is not limited to the following manufacturing method.

The coating layer may be formed by, for example, a physical vapor deposition method. Examples of the physical vapor deposition method may include an ion plating method and a sputtering method. For example, when the coating layer is formed by an ion plating method, the coating layer may be fabricated by the following method.

First, an example of a manufacturing method of the intermediate layer will be described. The base body is heated under a reduced pressure environment of 8×10⁻³ to 1×10⁻⁴ Pa to set a surface temperature to 500 to 600° C. Next, an argon gas is introduced as an atmospheric gas, and the pressure is maintained at 3.0 Pa. Next, a bias voltage is set to −400 V, and an argon bombardment treatment is performed for 11 minutes. Next, the pressure is reduced to 0.1 Pa, an arc current of 130 to 160 A is applied to a Ti metal evaporation source, and a treatment is performed for 0.3 minutes to form a Ti-containing intermediate layer as an intermediate layer on the surface of the base body. In order to fabricate an intermediate layer having a desired thickness, the argon bombardment treatment and the Ti-containing intermediate layer forming treatment may be repeated. However, in the second and subsequent argon bombardment treatments, the bias voltage is set to −200 V.

An example of a method for fabricating the first coating layer by an ion plating method will be described. First, as an example, each metal target of Cr, Si, and Al, a composite alloy target, or a sintered body target is prepared.

Next, the target serving as a metal source is vaporized and ionized by arc discharge, glow discharge, or the like. The ionized metal is reacted with a nitrogen (N₂) gas of a nitrogen source and deposited on the surface of the base body. The AlCrSiN layer can be formed by the procedure described above.

In the above procedure, the temperature of the base body may be set to 500 to 600° C., the nitrogen gas pressure may be set to 1.0 to 6.0 Pa, a direct-current bias voltage of −50 to −200 V may be applied to the base body, and the arc discharge current may be set to 100 to 200 A.

A composition of the first coating layer can be adjusted by independently controlling the voltage and current values at the time of arc discharge and glow discharge applied to the aluminum metal target, the chromium metal target, the aluminum-silicon composite alloy target, and the chromium-silicon composite alloy target, for each target. The composition of the coating layer can be adjusted by controlling the coating time and the atmospheric gas pressure. In an example of the embodiment, an amount of ionization of the target metal can be changed by changing the voltage and current values at the time of arc discharge and glow discharge. By periodically changing the current value at the time of arc discharge or glow discharge for each target, the amount of ionization of the target metal can be periodically changed. The amount of ionization of the target metal can be periodically changed by periodically changing the current value at the time of arc discharging or glow discharging of the target at intervals of 0.01 to 0.5 minutes. Consequently, in the thickness direction of the coating layer, the content ratio of each metal element can be changed in each period.

When carrying out the above procedure, the composition of Al, Si and Cr is changed so that the amounts of Al and Si are decreased and the amount of Cr is increased, and then the composition of Al, Si and Cr is changed so that the amounts of Al and Si are increased and the amount of Cr is decreased, whereby the first coating layer including the first layer and the second layer can be fabricated.

Next, an example of a manufacturing method of the second coating layer that is a TiSiN layer will be described.

As with the first coating layer, the second coating layer may also be formed by the physical vapor deposition method. As an example, first, a Ti metal target and a Ti—Si composite alloy target are prepared. Then, the voltage and current values at the time of arc discharge and glow discharge applied to the prepared targets are independently controlled for each target, whereby the second coating layer having a striped structure can be fabricated.

In the above procedure, the temperature of the base body may be 500 to 600° C., the nitrogen gas pressure may be set to 1.0 to 6.0 Pa, the direct-current bias voltage of −50 to −200 V may be applied to the base body, the arc discharge current may be set to 100 to 200 A, and the change cycle of the arc current may be set to 0.01 to 0.5 minutes.

### Example

An example of the present disclosure will be specifically described below. The present disclosure is not limited to the following example.

Sample No. 1 was a coated tool in which the base body was made of WC, the intermediate layer was made of a Ti-containing layer, the first coating layer was made of an AlCrSiN layer, and the second coating layer was made of a TiSiN layer. Sample No. 1 corresponds to the example of the present disclosure.

The base body was heated under a reduced pressure environment of 1×10⁻³ Pa to set a surface temperature to 550° C. Next, an argon gas was introduced as an atmospheric gas, and the pressure was maintained at 3.0 Pa. Next, a bias voltage was set to −400 V, and an argon bombardment treatment was performed for 11 minutes. Then, the pressure was reduced to 0.1 Pa, and an arc current of 150 A was applied to the Ti metal evaporation source, and a treatment was performed for 0.3 minutes to form a Ti-containing layer on the surface of the base body. The argon bombardment treatment and the Ti-containing layer forming treatment were repeated three times in total to form an intermediate layer having a layer thickness of 8 nm. However, in the second and third argon bombardment treatments, the bias voltage was set to −200 V.

### Treatment Conditions of Argon Bombardment Treatment

(1) Bias voltage: −400 V
(2) Pressure: 3 Pa
(3) Treatment time: 11 minutes

### Film Forming Conditions of Ti-Containing Layer

(1) Arc current: 150 A
(2) Bias voltage: −400 V
(3) Pressure: 0.1 Pa
(4) Treatment time: 0.3 minutes

### Conditions of Second and Subsequent Argon Bombardment Treatments

(1) Bias voltage: −200 V

(2) Pressure: 3 Pa

(3) Treatment time: 1 minute

The intermediate layer may contain other metal elements by diffusion. For example, when the intermediate layer contains Ti, the intermediate layer may contain 50 to 98 atomic % of a metal element other than Ti.

Then, the first coating layer was formed. An atmospheric gas and a N₂ gas as an N source were introduced into a chamber in which the base body was accommodated, and the internal pressure of the chamber was maintained at 3 Pa. Next, a bias voltage of −130 V and arc currents of 135 to 150 A, 120 to 150 A, and 110 to 120 A were applied to the Al metal, Cr metal, and Al₅₀Si₅₀ alloy evaporation sources, respectively, for 15 minutes, with each arc current repeatedly applied at a cycle of 0.04 minutes, whereby an Al₅₀Cr₃₉Si₁₁N layer as the first coating layer having an average thickness of 1.8 μm was formed.

Then, the second coating layer was formed. A bias voltage of −100 V and arc currents of 100 to 200 A and 100 to 200 A were applied to the Ti metal and Ti₅₀Si₅₀ alloy evaporation sources, respectively, for 10 minutes, with each arc current repeatedly applied at a cycle of 0.04 minutes, whereby a Ti₈₆Si₁₄N layer as the second coating layer having an average thickness of 1.2 μm was formed.

The X-ray intensity distribution of Sample No. 1 was measured under the following conditions. Note that when the normal to the sample surface is on a plane determined by an incident ray and a diffracted ray, the α angle is set to 90°. When the a angle is 90°, it becomes a center point on the positive pole figure.
(1) Flat plate collimator
(2) Scanning method: concentric circle
(3) β scanning range: 0° or greater and 360° or less/2.5° pitch
(4) θ fixed angle: A diffraction angle of the (111) plane of the Ti₈₆Si₁₄N crystal is set to an angle at which the diffraction intensity becomes the highest between 36.0° and 38.0°. The diffraction angle of the (200) plane of the Ti₈₆Si₁₄N crystal is set to an angle at which the diffraction intensity becomes the highest between 42.0° and 44.0°.
(5) a scanning range: 0° or greater and 90° or less/2.5° steps
(6) Target: CuKα, voltage: 45 kV, current: 40 mA

A cutting test was conducted using a coated ball end mill having a 2KMBL0200-0800-S4 shape formed with a coating layer. In the cutting test, the cutting edge flank face was observed for each cut length of 1 m, the presence or absence of chipping was observed with a microscope, and the number of impacts calculated from the cut length at the time when chipping occurred was obtained. Test conditions are set forth below. As comparative examples, conventional products (Samples No. 2 to No. 8) were also subjected to the same test.

### Cutting Test Conditions

(1) Work material: SKD11H
(2) Rotational speed: 16900 min⁻¹
(3) Table feed: 1320 mm/min
(4) Cutting amount (ap×ae): 0.08 mm×0.2 mm
(5) Cutting state: Wet
(6) Coolant: Oil mist

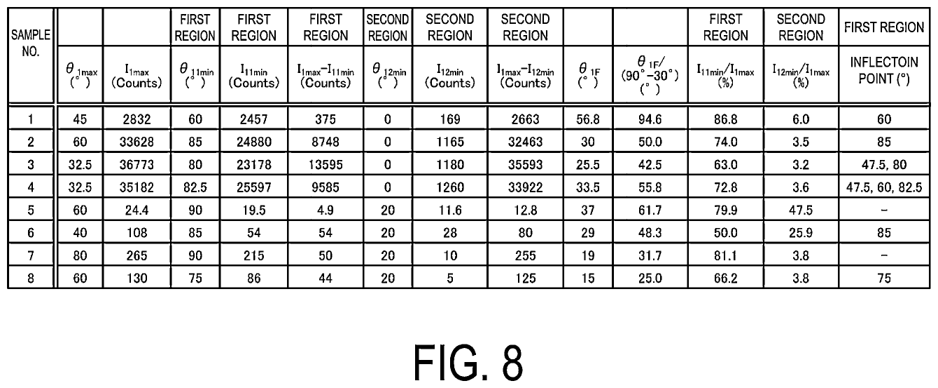

As for X-Ray Intensity Distribution of Positive Pole Figure Related to (111) Plane FIG. 8 is a table summarizing various numerical values on the X-ray intensity distribution of the positive pole figure related to the (111) plane of the cubic crystal contained in the coating layer for Samples No. 1 to No. 8.

As shown in FIG. 8, in Sample No. 1, the angle region (θ_{1F}) in which the X-ray intensity was 85% or more of I₁ₘₐₓ that is the maximum value of the X-ray intensity was 56.8°. The occupying ratio of θ_{1F} in the angle region of 30° or greater and 90° or less, i.e., θ_{1F}/(90°-30°) was 94.6%.

In contrast, the θ_{1F}/(90°-30°) values in Samples No. 2 to No. 8 are 50.0%, 42.5%, 55.8%, 61.7%, 48.3%, 31.7%, and 25.0%, respectively. That is, in each of Samples No. 2 to No. 8, the occupying ratio of θ_{1F} in the angle region of 30° or greater and 90° or less is less than 90%.

In Sample No. 1, the difference (I₁ₘₐₓ−I₁₁ₘᵢₙ) between the maximum value I₁ₘₐₓ of the X-ray intensity and the minimum value I₁₁ₘᵢₙ of the X-ray intensity in the first region was 375, and the difference between the maximum value I₁ₘₐₓ of the X-ray intensity and the minimum value I₁₂ₘᵢₙ of the X-ray intensity in the second region was 2663. In Sample No. 1, the ratio of I₁₁ₘᵢₙ to I₁ₘₐₓ, i.e., I₁₁ₘᵢₙ/I₁ₘₐₓ was 86.8%.

As described above, in Sample No. 1, the difference (I₁ₘₐₓ−I₁₁ₘᵢₙ) between I₁ₘₐₓ and I₁₁ₘᵢₙ was smaller than the difference between I₁ₘₐₓ and I₁₂ₘᵢₙ, and I₁₁ₘᵢₙ was 85% or more of I₁ₘₐₓ. On the other hand, in all of Samples No. 2 to No. 8, I₁₁ₘᵢₙ was less than 85% of I₁ₘₐₓ.

In Sample No. 1, the ratio of I₁₂ₘᵢₙ to I₁ₘₐₓ, i.e., I₁₂ₘᵢₙ/I₁ₘₐₓ was 6.0%. That is, in Sample No. 1, 112 min is 5% or greater and 20% or less of I₁ₘₐₓ. On the other hand, in Samples No. 2 to No. 4, No. 7, and No. 8, 112 min was less than 5% of I₁ₘₐₓ, and in Samples No. 5 and No. 6, 112 min was greater than 20% of I₁ₘₐₓ.

In Sample No. 1, θ₁ₘₐₓ was 45°. That is, in Sample No. 1, θ₁ₘₐₓ was 35° or greater and 55° or less. On the other hand, in Samples No. 2 to No. 8, the θ₁ₘₐₓ values were 60°, 32.5°, 32.5°, 60°, 40°, 80°, and 60°, respectively.

Sample No. 1 has an inflection point at a position of 60°. That is, Sample No. 1 has one inflection point in the first region. On the other hand, Sample No. 2 has an inflection point at a position of 85° in the first region, Sample No. 3 has inflection points at positions of 47.5° and 80° in the first region, and Sample No. 4 has inflection points at positions of 47.5°, 60°, and 82.5° in the first region. Sample No. 5 has no inflection point, Sample No. 6 has an inflection point at a position of 85° in the first region, Sample No. 7 has no inflection point, and Sample No. 8 has an inflection point at a position of 75° in the first region.

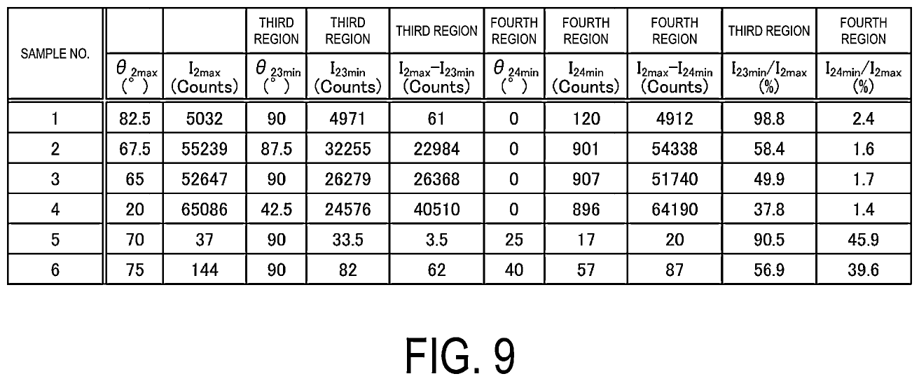

X-Ray Intensity Distribution of Positive Pole Figure Related to (200) Plane FIG. 9 is a table summarizing various numerical values on the X-ray intensity distribution of the positive pole figure related to the (200) plane of the cubic crystal included in the coating layer for Samples No. 1 to No. 6.

As shown in FIG. 9, in Sample No. 1, the difference (I₂ₘₐₓ−I₂₃ₘᵢₙ) between the maximum value I₂ₘₐₓ of the X-ray intensity and the minimum value I₂₃ₘᵢₙ of the X-ray intensity in the third region was 61, and the difference (I₂ₘₐₓ−I₂₄ₘᵢₙ) between I₂ₘₐₓ and the minimum value I₂₄ₘᵢₙ of the X-ray intensity in the fourth region was 4912. In Sample No. 1, the ratio of I₂₃ₘᵢₙ to I₂ₘₐₓ, i.e., I₂₃ₘᵢₙ/I₂ₘₐₓ was 98.8%. That is, in Sample No. 1, the difference (I₂ₘₐₓ−I₂₃ₘᵢₙ) between I₂ₘₐₓ and I₂₃ₘᵢₙ is smaller than the difference (I₂ₘₐₓ−I₂₄ₘᵢₙ) between I₂ₘₐₓ and I₂₄ₘᵢₙ, and I₂₃ₘᵢₙ is 95% or more of I₂ₘₐₓ.

On the other hand, in Samples No. 2 to No. 6, the values for the ratio of I₂₃ₘᵢₙ to I₂ₘₐₓ, i.e., I₂₃ₘᵢₙ/I₂ₘₐₓ were 58.4%, 49.9%, 37.8%, 90.5%, and 56.9%, respectively, which were all less than 95%.

In Sample No. 1, the ratio of I₂₄ₘᵢₙ to I₂ₘₐₓ was 2.4%. That is, in Sample No. 1, I₂₄ₘᵢₙ is 2% or greater and 35% or less of I₂ₘₐₓ. On the other hand, in Samples No. 2 to No. 4, I₂₄ₘᵢₙ is less than 2% of I₂ₘₐₓ, and in Samples No. 5 and No. 6, 124 min is greater than 35% of I₂ₘₐₓ. In Sample No. 1, θ₂ₘₐₓ was 82.5°. That is, in Sample No. 1, θ₂ₘₐₓ is 70° or greater and 85° or less. On the other hand, in Samples No. 2 to No. 6, the θ₂ₘₐₓ values were 67.5°, 65°, 20°, 70°, 70°, and 75°, respectively.

### Cutting Test Results

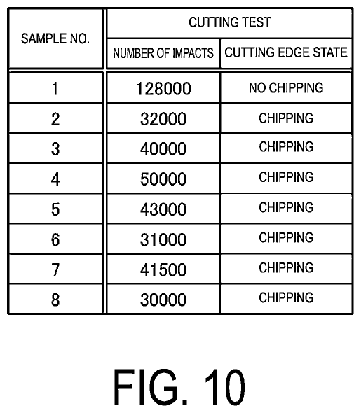

FIG. 10 is a table summarizing results of cutting tests performed on Samples No. 1 to No. 8. As shown in FIG. 10, in Sample No. 1 corresponding to an example of the present disclosure, chipping did not occur even at a number of impacts of 128000. On the other hand, in Samples No. 2 to No. 8 as comparative examples, chipping occurred at a number of impacts of 30000 to 50000.

As described above, in Sample No. 1 corresponding to an example of the present disclosure, the number of impacts until chipping occurred was larger, as compared with Samples No. 2 to No. 8 as comparative examples. From this result, it can be seen that the coated tool according to the present disclosure has high impact resistance.

As described above, a coated tool (as an example, the coated tool 1) according to an embodiment includes a base body (as an example, the base body 10), and a coating layer (as an example, the coating layer 20) of at least one layer located on the base body. The coating layer contains a cubic crystal composed of at least one element selected from Groups 4a, 5a and 6a elements in the periodic table, Al and Si, and at least one element selected from C and N. The coating layer has a maximum value (I₁ₘₐₓ) of the X-ray intensity in a measurement range of an α-axis angle of 0° or greater and 90° or less on an α-axis X-ray intensity distribution of a positive pole figure related to a (111) plane of a cubic crystal, and an angle region (θ_{1F}) having an X-ray intensity of 85% or more of I₁ₘₐₓ occupies 90% or more in a region of 30° or greater and 90° or less.

Therefore, the coated tool according to the embodiment can enhance the impact resistance.

Note that the shape of the coated tool 1 illustrated in FIG. 1 is merely an example and does not limit the shape of the coated tool according to the present disclosure. The coated tool according to the present disclosure may include a body having, for example, a rotation axis and a rod-like shape extending from a first end toward a second end, a cutting edge located at the first end of the body, and a groove extending in a spiral shape from the cutting edge toward the second end of the body.

Further effects and variations can be readily derived by those skilled in the art. Thus, a wide variety of aspects of the present invention are not limited to the specific details and a representative embodiment represented and described above. Accordingly, various changes are possible without departing from the spirit or scope of the general inventive concepts defined by the appended claims and their equivalents.

1. A coated tool comprising:
a base body; and
a coating layer of at least one layer located on the base body, wherein
the coating layer contains a cubic crystal composed of at least one element selected from Groups 4a, 5a and 6a elements in the periodic table, Al and Si, and at least one element selected from C and N, and
the coating layer has a maximum value (I₁ₘₐₓ) of an X-ray intensity in a measurement range of 0° or greater and 90° or less in an X-ray intensity distribution of an α-axis of a positive pole figure related to a (111) plane of the cubic crystal, and an angle region (θ_{1F}) having an X-ray intensity of 85% or more of I₁ₘₐₓ occupies 90% or more in a region of 30° or greater and 90° or less.

2. The coated tool according to claim 1, wherein
in the positive pole figure related to the (111) plane, in the coating layer, a difference (I₁ₘₐₓ−I₁₁ₘᵢₙ) between a minimum value (I₁₁ₘᵢₙ) of the X-ray intensity in a first region, which is a region on a higher angle side than an α-axis angle (θ₁ₘₐₓ) representing the I₁ₘₐₓ, and the I₁ₘₐₓ is smaller than a difference (I₁ₘₐₓ−I₁₂ₘᵢₙ) between a minimum value (I₁₂ₘᵢₙ) of the X-ray intensity in a second region, which is a region on a lower angle side than the θ₁ₘₐₓ, and the I₁ₘₐₓ, and the I₁₁ₘᵢₙ is 85% or more of the I₁ₘₐₓ.

3. The coated tool according to claim 2, wherein
the coating layer has at least one inflection point in the first region in the positive pole figure related to the (111) plane.

4. The coated tool according to any one of claim 1, wherein
in the positive pole figure related to the (111) plane, in the coating layer, the I₁₂ₘᵢₙ is 5% or greater and 20% or less of the I₁ₘₐₓ.

5. The coated tool according to claim 1, wherein
in the positive pole figure related to the (111) plane, in the coating layer, the α-axis angle (θ₁ₘₐₓ) representing the I₁ₘₐₓ is 35° or greater and 55° or less.

6. A cutting tool comprising:
a rod-like holder comprising a pocket at an end portion thereof; and
the coated tool according to claim 1 located in the pocket.
